(19) United States
(12) Patent Application Publication
(10) Pub. No.: US 2005/0007812 A1
(43) Pub. Date: Jan. 13, 2005

(54) Image forming apparatus and method of forming image

(75) Inventor: Tsuyoshi Kowari, Nagano (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/857,623

(22) Filed: May 28, 2004

(30) Foreign Application Priority Data
Jun. 3, 2003 (JP) P2003-157707
Jun. 3, 2003 (JP) P2003-157708

(51) Int. Cl. G11C 11/24

(52) U.S. Cl. 365/149

(57) ABSTRACT

An image forming apparatus includes a main power source, a replaceable unit, a switch and a memory. The main power source includes a first power source which supplies power to a high load unit and a second power source which supplies power to a low load unit. The replaceable unit is used for image formation. The switch switches between an image forming operation mode and a non-image forming operation mode. The memory is supplied with the power from the second power source. Lifetime management information of the replaceable unit is stored in the memory during the image forming operation mode.

### BACKGROUND OF THE INVENTION

The present invention relates to an image forming apparatus and method of forming an image in which the number of writing to a memory is not limited, and lifetime management information of a replaceable unit is updated and written to the memory even during main-power shutdown.

An image forming apparatus, which forms an image by using toners, checks toner consumption or the remaining amount to manage the lifetime of toner cartridges for the purpose of maintenance such as toner replenishment and image quality. In addition, the lifetime of exposure units, charging units, and fixing units are sometimes managed as replaceable units. The lifetime management information is stored in memories. Unit adjustment information such as density adjustment information are also stored in memories.

It is desirable to store the various set information of the image forming apparatus in nonvolatile memories so as not to be erased even when main power is shut off. In the nonvolatile memories, an electrically erasable programmable read-only memory (EEPROM) has the advantage of low price. JP-B-2910821 describes a structure in which the various set information is stored in the EEPROM.

When main power is shut off or fails, lifetime management data stored in a memory having the EEPROM is sometimes corrupted, or incorrect data is stored in the memory by application of instantaneous voltage. In order to counter such situations, the applicant has disclosed a lifetime management device for image forming apparatus which recovers data in JP-A-2000-172133.

This type of image forming apparatus includes three-system power sources, a 5V power source for a control system for feeding control-system components such as a CPU, a 24V power source for a driving system for feeding driving-system components such as a motor, and a 100V power source for feeding a fixing heater. When a main-source switch is turned on, the power sources are activated to render the components available. The memory which stores the various information is connected to the 5V power source.

To meet various requirements from users, the type of image forming apparatus having a print function to which additional image processing units are added have been developed. Examples of this type of units include a unit, which is called a multibin unit, having bins for dividing and ejecting image-formed recording media and a unit including a stapler and an output tray, which is called a finisher, to combine multiple image-formed recording media with staples and eject them. To join the additional units with image forming apparatus having a print function, the additional units are supplied with power from the image forming apparatus.

Such additional units need a controller for operating the additional units, a display, a memory, etc. The components including the memory and the display are connected to the 5V power source. Accordingly, providing the additional units increases a load connected to the 5V power source of the image forming apparatus.

When main power of the image forming apparatus is shut off, the voltage of the 24V power source decreases gradually to 0V with time. The sequence of the voltage of the 5V power source is set to decrease later than that of the 24V power source. The interruption of the main power is determined by detecting a decrease in voltage of the 24V power source to a specified level by a voltage sensor. It is necessary to make an information writing process to a memory which is connected to the 5V power source during main-power shutdown in a short time after the specified level of decrease in voltage of the 24V power source has been detected until the voltage of the 5V power source starts to decrease.

In order to meet the recent requirement for power consumption, the type of image forming apparatus have been developed which switches between a printing operation mode and a nonprinting operation mode. When the image forming apparatus are operated in the nonprinting operation mode, high-current-capacity components such as scanner motors are stopped and only low loads, such as a fan, are connected to the 24V power source. Therefore, when main power is shut off during operation in the nonprinting operation mode, the voltage shows a mild decreasing characteristic because a current consumption of the 24V power source is low. When the additional units are added to the image forming apparatus to expand its function, the load connected to the 5V power source increases, as described above. Accordingly, when the image forming apparatus are operated in the nonprinting operation mode, the current consumption of the 24V power source is sometimes minimized, and the load to the 5V power source is maximized.

FIG. 7 is a characteristic diagram of an example of the voltage drop characteristics of the image forming apparatus during operation in the nonprinting operation mode in a case that the main power of the 24V power source and the 5V power source is shut off. In FIG. 7, the main power is shut off at time ta. The 24V power source decreases in voltage with time to reach 0V at time td, as indicated by characteristic (A). The 5V power source starts to decrease in voltage from time tb, later than time ta, to reach 0V at time tc, as indicated by characteristic (B). The specified level of decrease in voltage of the 24V power source by main-power shutdown is set at a point in time when ten percent of the rated voltage, 2.4V, decreases to 21.6V.

In JP-B-2910821, various set information of the image forming apparatus is stored in an EEPROM. Since the EEPROM has a limitation in the number of times of writing, JP-B-2910821 provides the following procedure: updating set information and storing it in a volatile memory in a printing operation mode, and storing the set information stored in the volatile memory in a nonvolatile memory (EEPROM) when the operating mode shifts to a standby mode.

The number of times of writing to the nonvolatile memory is limited as described in JP-B-2910821. However, JP-B-2910821 has the problem that necessary information such as lifetime management information cannot be updated when main power is suddenly shut off by power failure etc. Also it needs a special control to limit the number of times of writing to the nonvolatile memory, posing the problem of complicating the structure of the control system.

JP-A-2000-172133 describes data protection during main-power shutdown when a nonvolatile memory is used. Also in JP-A-2000-172133, since the EEPROM is used as the nonvolatile memory, the number of times of writing is limited. The data protection during main-power shutdown requires complicated processing, posing the problem of complicating the procedure.

If a capacitor for keeping the 5V power for a predetermined time is connected to the 5V power source when a specified-level decrease in voltage of the 24V power source is detected, the memory can continue to write information during main-power shutdown. However, in order to execute stable information-writing operation at that time, the capacity of the capacitor must be increased, it causes a problem of increasing cost.

Particularly, when main power is shut off during operation in the nonprinting operation mode in a state that the additional units is connected to the image forming apparatus, the voltage of the 5V power source starts to decrease at the point in time when it is detected that the voltage of the 24V power source is decreased to a specified level, that is 21.6V, as shown in FIG. 7. Therefore, necessary information including lifetime management information cannot be stored in a memory when main power is shut off, posing the problem of making accurate lifetime management impossible.

### SUMMARY OF THE INVENTION

It is therefore an object of the present invention to provide an image forming apparatus and method in which the number of times of writing is not limited and lifetime management information can be updated and stored in a memory even during main-power shutdown.

(1). An image forming apparatus, comprising:
a main power source, which includes:
   a first power source, which supplies power to a high load unit;
   a second power source, which supplies power to a low load unit;
a replaceable unit, which is used for image formation;
a switch, which switches between an image forming operation mode and a non-image forming operation mode; and
a memory, which is supplied with the power from the second power source,
wherein lifetime management information of the replaceable unit is stored in the memory during the image forming operation mode.

(2). The image forming apparatus as set forth in above (1), wherein the memory has a ferroelectric memory (FRAM).

(3). The image forming apparatus as set forth in above (1), wherein the power supplied from the first power source is greater than the power supplied from the second power source; and
wherein a current capacity of the high load unit is greater than that of the low load unit.

(4). The image forming apparatus as set forth in above (1), wherein a total current capacity of the high load unit in the image forming operation mode is greater than that of the high load unit in the non-image forming operation mode.

(5). The image forming apparatus as set forth in above (1), wherein an inclination of a voltage drop of the first power source after the main power source is shut off in the image forming operation mode is greater than that of the first power source after the main power source is shut off in the non-image forming operation mode.

(6). The image forming apparatus as set forth in above (1), wherein the image forming operation mode is same as the non-image forming operation mode in a period of the second power source from a shut off of the main power source until a voltage of the second power source starts to decrease.

(7). The image forming apparatus as set forth in above (1), wherein an additional unit which expands a function of the image formation is detachably mounted on the image forming apparatus; and
wherein the additional unit is supplied with the power from the second power source.

(8). The image forming apparatus as set forth in above (1), further comprising:
a detector, which detects a voltage drop of the first power source when the main power source is shut off,
wherein the lifetime management information is stored in the ferroelectric memory within a period from a voltage of the first power source decreases to a determined level until a voltage of the second power source starts to decrease.

(9). The image forming apparatus as set forth in above (1), further comprising:
an image supporting member, which supports an electrostatic latent image; and
a rotary developing member, which supports toners stored in a plurality of toner cartridges on a surface thereof,
wherein the rotary developing member carries different-color toners to a position opposed to the image supporting member in sequence by rotating in a specified rotating direction;
wherein a developing bias voltage is applied between the image supporting member and the rotary developing member;
wherein the toners are carried from the rotary developing member to the image supporting member; and
wherein the electrostatic latent image is developed so that a toner image is formed on the image supporting member.

(10). The image forming apparatus as set forth in above (1), further comprising:
an image supporting member, which supports an electrostatic latent image; and
a developing member, which is disposed around the image supporting member in a direction of rotation of the image supporting member, and which supports multiple-color toners on a surface thereof;
wherein the image supporting member carries the different-color toners of the developing member to a position opposed to the image supporting member in sequence by rotating in a specified rotating direction;
wherein a developing bias voltage is applied between the image supporting member and the developing member;
wherein the toners are carried from the developing member to the image supporting member; and
wherein the electrostatic latent image is developed so that a toner image is formed on the image supporting member.

(11). The image forming apparatus as set forth in above (9), wherein the toner image formed on the image supporting member is transferred to an intermediate transfer member.

(12). A method of forming an image, comprising the steps of:
providing an image supporting member which supports an electrostatic latent image;
providing a replaceable unit used for image formation;
forming an image on the image supporting member in an image forming operation mode; and
storing lifetime management information of the replaceable unit in a ferroelectric memory (FRAM) which is connected to a control system power source in the image forming operation mode.

(13). The method as set forth in above (12), further comprising the steps of:
detecting voltage of a driving system power source;
first determining whether or not the voltage of the driving system power source is decreased to a specified level;
second determining whether or not a main power source is shut off based on the first determining step; and
storing lifetime management information of the replaceable unit in the ferroelectric memory within a period from a shutoff of the main power source is detected until a voltage of a control system power source supplied with power from the main power source starts to decrease.

(14). An image forming apparatus, comprising:
a main power source, which includes:
   a first power source, which supplies power to a high load unit;
   a second power source, which supplies power to a low load unit;
a replaceable unit, which is used for image formation;
a switch, which switches between an image forming operation mode and a non-image forming operation mode;
a memory, which is supplied with the power from the second power source; and
a controller, which restricts a storing of lifetime management information of the replaceable unit in the memory during the non-image forming operation mode.

(15). The image forming apparatus as set forth in above (14), wherein the memory has a ferroelectric memory (FRAM).

(16). A method of forming an image, comprising the steps of:
providing an image supporting member which supports an electrostatic latent image;
providing a replaceable unit used for image formation;
forming an image on the image supporting member in an image forming operation mode; and
restricting a storing of lifetime management information of the replaceable unit in a ferroelectric memory (FRAM) which is connected to a control system power source in a non-image forming operation mode.

Also, according to the present invention, there is provided an image forming apparatus, comprising a driving-system power source and a control-system power source powered by a main power source; a replaceable unit used for image formation; and a controller for switching operation mode between a printing operation mode and a nonprinting operation mode, to which an image-processing unit can be added, wherein the added unit is supplied with power from the image forming apparatus. The control-system power source connects to a ferroelectric memory (FRAM) for storing the lifetime management information of the replaceable unit. The update of the lifetime management information to be written to the memory is executed in the printing operation mode. Since the lifetime management information is written to the nonvolatile ferroelectric memory (FRAM), the number of times of writing is not limited and the lifetime management information can be updated accurately. The update of the lifetime management information is executed in the printing operation mode in which current consumption of the driving-system power source is large. Accordingly, even if the load of the 5V power source is increased by adding an additional unit to expand the function of the image forming apparatus, the lifetime management information can be updated without problems.

According to the present invention, the image forming apparatus further includes a detector for detecting voltage drop of the driving-system power source when the main power is shut off; and a controller for updating information to be stored in the memory within the time after the voltage decreases to a specified level until the voltage of the control-system power source starts to decrease. Accordingly, the lifetime management information can be updated during main-power shutdown without increasing the capacity of a capacitor connected to the control-system power source. This reduces the cost for updating the lifetime management information.

The image forming apparatus according to the invention further includes an image supporting member capable of supporting an electrostatic latent image and a rotary developing member. The rotary developing member supports toners stored in a plurality of toner cartridges on the surface thereof, carries the different color toners to a position opposed to the image supporting member in sequence by rotating in a specified rotating direction, and applies developing bias between the image supporting member and the rotary developing member to move the toners from the rotary developing member to the image supporting member, thereby developing the electrostatic latent image, thereby forming a toner image. Accordingly, in the image forming apparatus including the rotary developing member shown in FIG. 2, the lifetime management information of the units used for image formation can be updated accurately, allowing the replacement time of the units to be known.

The image forming apparatus according to the invention further includes an image supporting member capable of supporting an electrostatic latent image and a developing member disposed around the image supporting member in the direction of rotation of the image supporting member for supporting multiple-color toners on the surface thereof, wherein the image supporting member carries the different-color toners of the developing member to a position opposed to the image supporting member in sequence by rotating in a specified rotating direction, and applies developing bias between the image supporting member and the developing member to move the toners from the developing member to the image supporting member, thereby developing the electrostatic latent image to form a toner image. Accordingly, in the image forming apparatus including a developing member disposed around the image supporting member in the direction of rotation of the image supporting member for supporting multiple-color toners on the surface thereof, the lifetime management information of the units used for image formation can be updated accurately, allowing the replacement time of the units to be known.

According to the present invention, preferably, the toner image formed on the image supporting member is transferred to an intermediate transfer member. Accordingly, in the image forming apparatus including the intermediate transfer member, the lifetime management information of the units used for image formation can be updated accurately.

In an image forming method using an image forming apparatus according to the invention, the apparatus includes at least an image supporting member capable of supporting an electrostatic latent image, a replaceable unit used for image formation, and an image-processing additional unit and the method includes the step of forming an image on the image supporting member with the operation mode set in a printing operation mode and the step of writing the lifetime management information of the replaceable unit to a ferroelectric memory (FRAM) connected to a control-system power source in the printing operation mode. Since the lifetime management information of the replaceable unit is stored in the ferroelectric memory (FRAM), the number of times of writing is not limited and as such, there is no need to execute special control for limiting the number of times of writing, as in the case of using an EEPROM as a memory, simplifying the structure of the control system.

The image forming method according to the invention further includes the step of determining main-power shutdown by detecting that the voltage of the driving-system power source has decreased to a specified level and the step of writing the lifetime management information to the memory within the time after the main-power shutdown is detected until the control-system power source starts to decrease in voltage. Accordingly, even if the main power is suddenly shut off by power failure etc., the lifetime management information can be stably updated.

In order to achieve the object, an image forming apparatus according to the present invention includes a driving-system power source and a control-system power source powered by a main power source; a replaceable unit used for image formation; and a controller for switching operation mode between a printing operation mode and a nonprinting operation mode, to which an image-processing unit can be added. The added unit is supplied with power from the image forming apparatus. The control-system power source connects to a memory for storing the lifetime management information of the replaceable unit. A controller is further provided which disables the update of the lifetime management information to be written to the memory in the nonprinting operation mode. In this way, the writing of the lifetime management information to the memory is disabled during operation in the nonprinting operation mode in which the current consumption of the driving-system power source is low. Accordingly, even if the load to the control-system power source is increased by adding an additional unit to expand the function of the image forming apparatus, the lifetime management information can be updated without problems. The lifetime management information can be updated accurately without breaking off the lifetime management information during main-power shutdown.

According to the present invention, preferably, a ferroelectric memory (FRAM) is used as a memory. Since lifetime management information is written to the nonvolatile ferroelectric memory (FRAM), the lifetime management information can be updated accurately without limitation to the number of times of writing.

According to the present invention, the image forming apparatus may further include a detector for detecting voltage drop of the driving-system power source when the main power is shut off and a controller for updating information to be stored in the memory within the time after the voltage decreases to a specified level until the voltage of the control-system power source starts to decrease. Accordingly, the lifetime management information can be updated during main-power shutdown without increasing the capacity of a capacitor connected to the control-system power source, thus reducing the cost.

The image forming apparatus according to the invention may further include an image supporting member capable of supporting an electrostatic latent image and a rotary developing member. The rotary developing member supports toners stored in a plurality of toner cartridges on the surface thereof, carries the different color toners to a position opposed to the image supporting member in sequence by rotating in a specified rotating direction, and applies developing bias between the image supporting member and the rotary developing member to move the toners from the rotary developing member to the image supporting member, thereby developing the electrostatic latent image, thereby forming a toner image. Accordingly, in the image forming apparatus including the rotary developing member, the lifetime management information of the units used for image formation can be updated accurately, allowing the replacement time of the units to be grasped.

The image forming apparatus according to the invention may further include an image supporting member capable of supporting an electrostatic latent image and a developing member disposed around the image supporting member in the direction of rotation of the image supporting member for supporting multiple-color toners on the surface thereof, wherein the image supporting member carries the different-color toners of the developing member to a position opposed to the image supporting member in sequence by rotating in a specified rotating direction, and applies developing bias between the image supporting member and the developing member to move the toners from the developing member to the image supporting member, thereby developing the electrostatic latent image to form a toner image. Accordingly, in the image forming apparatus including a developing member disposed around the image supporting member in the direction of rotation of the image supporting member for supporting multiple-color toners on the surface thereof, the lifetime management information of the units used for image formation can be updated accurately, allowing the replacement time of the units to be grasped.

According to the present invention, preferably, the toner image formed on the image supporting member is transferred to an intermediate transfer member. Accordingly, in the image forming apparatus including the intermediate transfer member, the lifetime management information of the units used for image formation can be updated accurately.

In an image forming method using the image forming apparatus according to the invention, the apparatus includes at least an image supporting member capable of supporting an electrostatic latent image, a replaceable unit used for image formation, and an image-processing additional unit and the method includes the step of forming an image on the image supporting member with the operation mode set in a printing operation mode and the step of disabling the writing of the image forming apparatus of the units to the memory connected to the control-system power source in a nonprinting operation mode. In this way, since the writing of the lifetime management information to the memory is disabled during operation in the nonprinting operation mode in which the current consumption of the driving-system power source is low, the update of the lifetime management information is not interrupted during main-power shutdown.

In the image forming method according to the present invention, preferably, a ferroelectric memory (FRAM) is used as a memory. Since the lifetime management information of the units is stored in the ferroelectric memory (FRAM), the number of times of writing is not limited and as such, there is no need to execute special control for limiting the number of times of writing, as in the case of using an EEPROM as a memory, simplifying the structure of the control system.

The image forming method according to the invention may further include the step of determining main-power shutdown by detecting that the voltage of the driving-system power source has decreased to a specified level and the step of writing the lifetime management information to the memory within the period after the main-power shutdown is detected until the control-system power source starts to decrease in voltage. Accordingly, even if the main power is suddenly shut off by power failure etc., the lifetime management information can be stably updated.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a characteristic diagram of an embodiment of the present invention;

FIG. 2 is a longitudinal sectional side view of an example of an image forming apparatus;

FIG. 3 is a block diagram of the electrical structure of the image forming apparatus of FIG. 2;

FIG. 4 is a block diagram of the embodiment of the present invention;

FIG. 5 is a structural diagram of another embodiment of the present invention;

FIG. 6 is a block diagram of the embodiment of the present invention; and

FIG. 7 is a characteristic diagram of a related example.

### DETAILED DESCRIPTION OF THE PREFERRED EMBODIMENTS

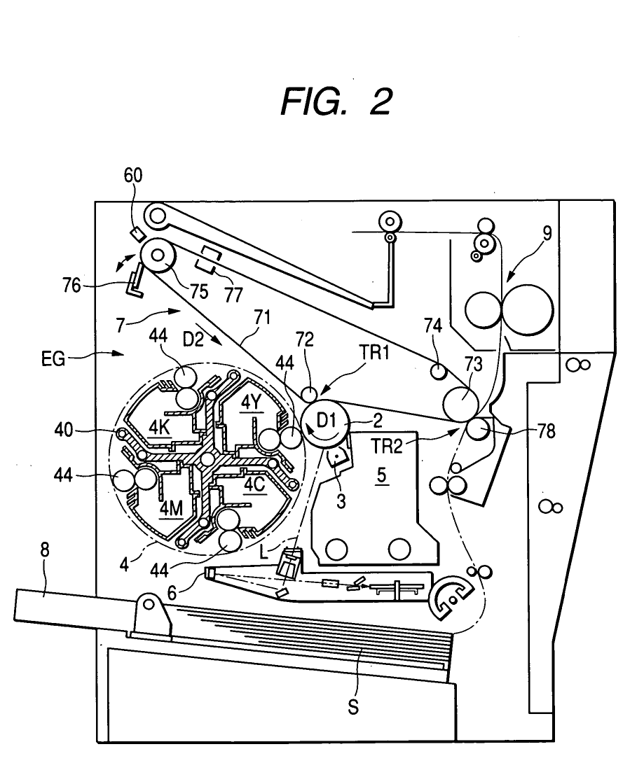

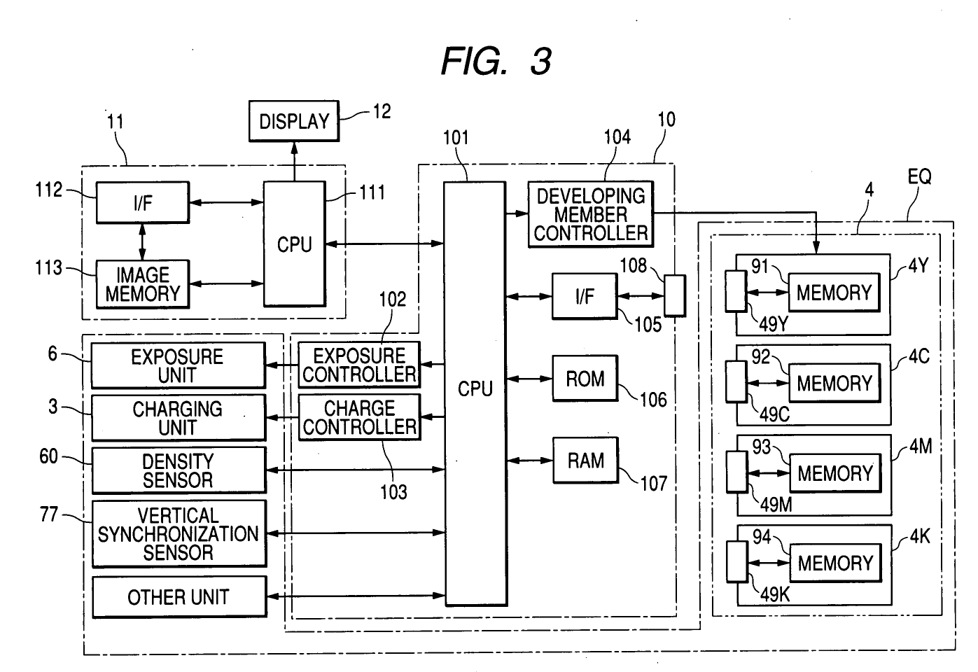

FIG. 2 is a longitudinal sectional side view of an image forming apparatus according to an embodiment of the present invention. FIG. 3 is a block diagram of the electrical structure of the image forming apparatus of FIG. 2. The image forming apparatus forms a full-color image by overlaying four toners, yellow (Y), cyan (C), magenta (M), and black (B), and a monochrome image by using only a black (B) toner. In the image forming apparatus of the invention, an image signal from an external device such as a host computer is sent to a main controller 11 in response to an image formation request from a user. At that time, an instruction signal is sent from the main controller 11 to an engine controller 10. The engine controller 10 controls each component of an engine EG according to the instruction signal to form an image corresponding to the image signal onto a sheet S (recording medium).

The engine EG includes a photoreceptor 2 serving as an image supporting member such that it can rotate in the direction of arrow D1 of FIG. 2. A charging unit 3, a rotary developing member 4, and a cleaning section 5 are disposed around the photoreceptor 2 along its rotating direction D1. The charging unit 3 is energized with charging bias from a charge controller 103 to uniformly energize the outer circumference of the photoreceptor 2 into a specified surface potential.

A light beam L is emitted from an exposure unit 6 toward the outer circumference of the photoreceptor 2 charged by the charging unit 3. The exposure unit 6 exposes the photoreceptor 2 with the light beam L according to a control instruction from an exposure controller 102 to form an electrostatic latent image corresponding to the image signal. The exposure unit 6 includes appropriate optical devices such as a lens and a mirror. The charging unit 3, the rotary developing member 4, the exposure unit 6, etc. used for image formation can be replaced and has maintainability. The lifetime management information of the units is stored in an FRAM (ferric RAM) 107, which will be described later.

When an image signal is given to a CPU 111 of the main controller 11 through an interface 112 from an external device such as a computer, a CPU 101 of the engine controller 10 outputs a control signal corresponding to the image signal to the exposure controller 102 at specified timing. The light beam L is emitted from the exposure unit 6 onto the photoreceptor 2 in accordance with the control signal to form an electrostatic latent image corresponding to the image signal onto the photoreceptor 2.

The formed electrostatic latent image is developed with toner by the rotary developing member 4. Specifically, in this embodiment, the rotary developing member 4 includes a support frame 40 which can rotate about the axis, a rotation drive section (not shown), etc. The rotary developing member 4 also includes a yellow developing member 4Y, a cyan developing member 4C, a magenta developing member 4M, and a black developing member 4K, which are detachable to the support frame 40 and contain respective colors therein. The developing members 4Y, 4C, 4M, and 4K are replaceable as toner cartridges.

As shown in FIG. 3, the rotary developing member 4 is controlled by a developing member controller 104. The rotary developing member 4 is rotated according to the control instruction from the developing member controller 104. The developing members 4Y, 4C, 4M, and 4K are positioned selectively in a specified developing position opposed to the photoreceptor 2 and apply a selected color toner onto the surface of the photoreceptor 2. The electrostatic latent image on the photoreceptor 2 is thus developed with the selected toner color.

The rotary developing member 4 forms color patch images by the engine controller 10 before image formation to the image forming region. The patch image includes a single solid-image patch (Vdc-patch) and a combination of a solid-image patch and a thin-line patch (E-patch). The thin-line patch is formed in, for example, what is called “one-on ten-off” formula in which a one-line patch image is formed but images of ten lines are not formed in the subscanning direction.

The main controller 11 forms a gradation-patch image to determine a density adjusting pattern. The gradation patch is formed by overlaying a single color or multiple colors on an image supporting member. The amounts of toner consumption of the patch image formed by the engine controller 10 and the patch image formed by the main controller 11 are stored in advance in a memory as offset values.

In the image forming apparatus, a developing roller 44 provided in the developing member (the yellow developing member 4Y in the example of FIG. 2) located in the corresponding position in the developing position is in contact with or opposed to the photoreceptor 2 with a specified gap therebetween. The developing roller 44 works as a toner-supporting member for supporting a toner charged on the surface by friction. The developing roller 44 rotates to carry the toner to a position opposed to the photoreceptor 2 on which an electrostatic latent image is formed.

Here, a developing bias in which direct voltage is superimposed to alternating voltage is applied from the developing member controller 104 to the developing roller 44. The toner carried on the developing roller 44 is partially adhered to part of the surface of the photoreceptor 2 by the developing bias depending on the surface potential. The electrostatic latent image on the photoreceptor 2 is thus developed as a toner image of the corresponding color.

The toner image developed by the developing member 4 is primarily transferred onto an intermediate transfer belt (intermediate transfer member) 71 of a transfer unit 7 in a primary transfer region TR1. The transfer unit 7 includes the intermediate transfer belt 71 bridged across a plurality of rollers 72 to 75 and a driving section (not shown) for driving the roller 73 to rotate the intermediate transfer belt 71 in a specified rotating direction D2. A secondary transfer roller 78 is provided in a position opposed to the roller 73 with the intermediate transfer belt 71 therebetween, the secondary transfer roller 78 being constructed such that it can be brought into or out of contact with the surface of the belt 71 by an electromagnetic clutch (not shown).

When a color image is transferred to the sheet S (recording medium), color toner images formed on the photoreceptor 2 are overlaid on the intermediate transfer belt 71, thereby forming the color image. The color image is transferred secondarily onto the sheet S ejected from a cassette 8 and carried to a secondary transfer region TR2 between the intermediate transfer belt 71 and the secondary transfer roller 78. The sheet S on which the color image has been formed is carried through a fixing unit 9 to an output tray provided on the upper surface of the apparatus body. The rotary developing member 4 is used for color image formation to the same amount of recording media.

The surface potential of the photoreceptor 2 after the toner image has first been transferred onto the intermediate transfer belt 71 is reset by an antistatic device (not shown). After a toner remaining on the surface of the photoreceptor 2 has been removed by the cleaning section 5, the photoreceptor 2 is next charged by the charging unit 3. The toner removed by the cleaning section 5 is collected to a toner tank (not shown).

A cleaner 76, a density sensor 60, and a vertical synchronization sensor 77 are disposed in the vicinity of the roller 75. Among them, the cleaner 76 can be moved closer to and separated from the roller 75 by an electromagnetic clutch (not shown). The blade of the cleaner 76 is brought into contact with the surface of the intermediate transfer belt 71 placed over the roller 75 with it shifted to the roller 75 to clean the toner remaining on the outer circumference of the intermediate transfer belt 71 after the secondary transfer. The toner removed by the blade of the cleaner 76 is collected into a wasted-transfer-toner tank.

The vertical synchronization sensor 77 is a sensor for detecting the reference position of the intermediate transfer belt (intermediate transfer member) 71, serving as a vertical synchronization sensor for generating a synchronizing signal outputted in relation to the rotation of the intermediate transfer belt 71, namely, a vertical synchronizing signal Vsync. The operation of the components of the apparatus is controlled according to the vertical synchronizing signal Vsync to coincide with the operation timings of the components with one another and overlay the color toner images accurately. The density sensor 60 is opposed to the surface of the intermediate transfer belt 71 and measures the optical density of the patch image formed on the outer circumference of the intermediate transfer belt 71.

As shown in FIG. 3, the developing members (toner cartridges) 4Y, 4C, 4M, and 4K include memories 91 to 94 serving as “memory devices” for storing data on the production rots, the use history, and the remaining amount of the contained toner of the developing members, respectively. The developing members 4Y, 4C, 4M, and 4K include connectors 49Y, 49C, 49M, and 49K, respectively.

The connectors 49Y, 49C, 49M, and 49K are connected selectively to a connector 108 on the body side, as necessary. Accordingly, data is transmitted/received between the CPU 101 of the engine controller 10 and the memories 91 to 94 through an interface 105 to control various information such as consumable-item management of the developing members (toner cartridges).

Although the embodiment transmits/receives data by mechanical engagement of the connector 108 on the body side and the connector 49K on the developing member side, it may transmits/receives data in noncontact with each other using electromagnetic technique such as radio communication. The memories 91 to 94 for storing specific data of the developing members 4Y, 4C, 4M, and 4K are desirably nonvolatile memories capable of storing the data even when power is shut off or the developing members are out of engagement with the body.

The image forming apparatus further includes a display 12, shown in FIG. 3 (not shown in FIG. 2). The display 12 displays a specified message according to a control instruction sent from the CPU 111 as necessary to inform the user of necessary information. For example, when troubles such as device failure or paper jam occur, it displays a message of notifying the user of the troubles. When the remaining amount of toner in any developing member decreases to a specified value or less, it displays a message of notifying that the time to replace the developing member has come.

The display 12 can be a liquid-crystal display device. Alternatively, it can be an alarm lamp that lights on and off as necessary. In addition to the visual notification by displaying a message, audio alarm devices such as a recorded voice message and a buzzer or a combination thereof can be used.

The main controller 11 includes an image memory 113 for storing an image sent from the external device such as the host computer through the interface 112; an ROM 106 for storing an operation program executed by the CPU 101 and control data for controlling the engine EG; and a nonvolatile ferroelectric random access memory (FRAM) 107 for storing lifetime management information of the toner cartridges and other replaceable units and various adjustment information such as density adjustment.

In the image forming apparatus with the above structure, the amount of remaining toner is required for each of the developing members (toner cartridges) 4Y, 4C, 4M, and 4K. This type of image forming apparatus has been developed in which two different capacities of toner cartridges, a high-capacity toner cartridge and a low-capacity toner cartridge, can be mounted to the same apparatus by replacement. In that case, the lifetime differs depending on the toner capacity of the high- or low-capacity toner cartridge. In other words, the fixed amount of remaining toner for determining the toner-cartridge replacement time is set to different values for the high- and low-capacity toner cartridges.

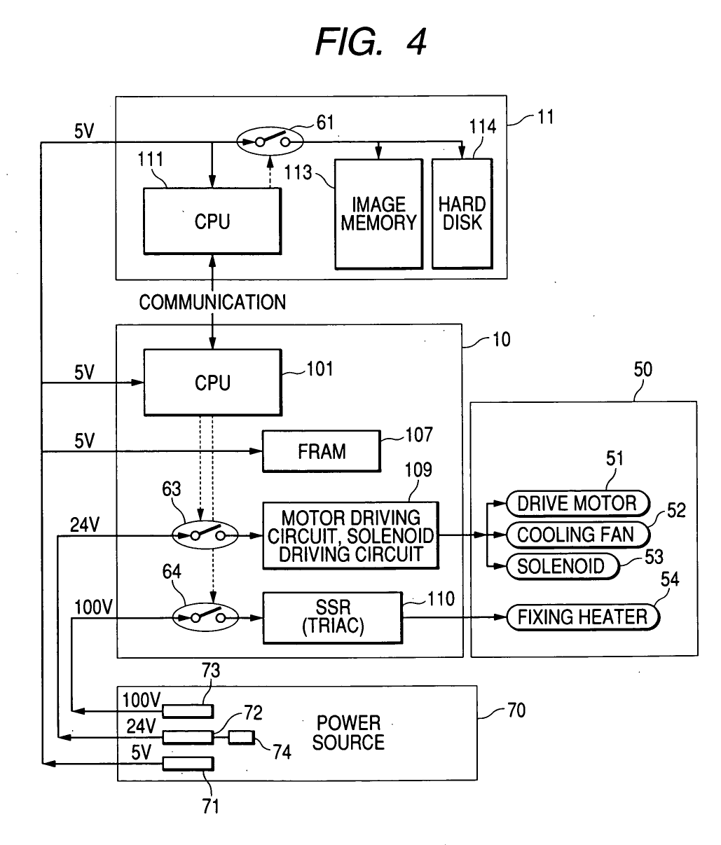

FIG. 4 is a partial block diagram of the connection of the power source and the controller of the invention. The components corresponding to those of FIG. 3 are given the same numerals. In FIG. 4, numeral 11 denotes a main controller; numeral 10 denotes an engine controller; numeral 50 denotes an engine mechanism of the image forming apparatus: and numeral 70 denotes a power source. The main controller 11 includes the CPU 111, the image memory 113, a hard disk 114, and a switch 61. The switch 61 can be a relay or an electronic switch. The switch 61 is opened or closed by the signal from the CPU 111 to connect or disconnect the 5V power source from the image memory 113 and the hard disk 114. The CPU 111 is supplied with the current of the 5V power source all the time.

The engine controller 10 includes the CPU 101, switches 63 and 64, the FRAM 107, a motor driving circuit, a solenoid driving circuit 109, and a triac (SSR) 110. The switches 63 and 64 can also be relays or electronic switches and opened or closed according to the signal from the CPU 101. The switch 63 connects or disconnects the 24V power source from the motor driving circuit and the solenoid driving circuit 109. The switch 64 connects or disconnects the 100V power source from the triac (SSR) 110. The CPU 101 is supplied with the current from the 5V power source.

Since the CPU 111 of the main controller 11 and the CPU 101 of the engine controller 10 are supplied with the current from the 5V power source all the time, they can mutually communicate with each other even during standby mode. Specifically, the CPU 111 of the engine controller 10 serves as master transmits a command for data processing to the CPU 101 of the engine controller 10 serving as slave. On the other hand, the CPU 101 of the engine controller 10 returns status information to the CPU 111.

The power source 70 includes three-system power sources, a 5V power source 71 for a control system, a 24V power source 72 for a driving system, and a 100V power source 73. The power sources supply necessary power to the specified components of the main controller 11 and the engine controller 10. When additional units are added, the power sources from the power source 70 are connected to the additional units. The voltage of the power sources is made of the voltage of the same main power source by using a voltage conversion member. Accordingly, when main power is shut off, the 5V, 24V, and 100V power sources are also shut off.

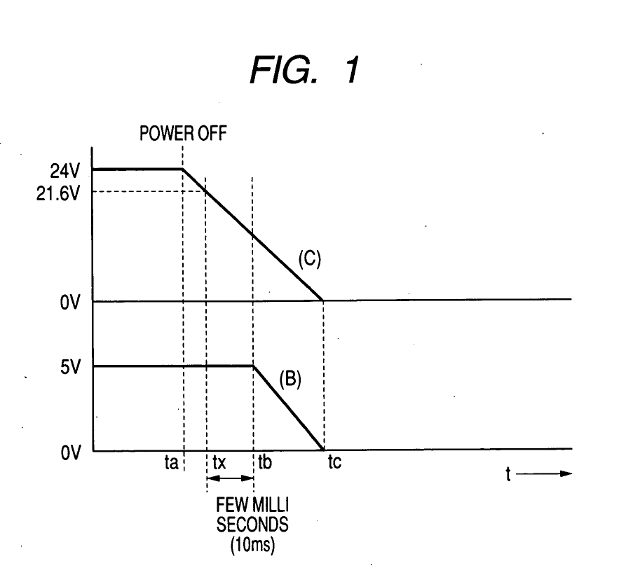

The 24V power source 72 includes a voltage sensor 74 for detecting a decrease in voltage when main power is shut off. The signal from the voltage sensor 74 is inputted to the CPU 101. The CPU 101 determines that the voltage of the 24V power source has decreased to 21.6V from the signal from the voltage sensor 74, as shown in FIG. 1, and controls the writing of lifetime management information to the FRAM 107 when main power is shut off. The control will be described later with reference to FIG. 1.

The engine mechanism 50 of the image forming apparatus includes a drive motor 51 for rotating the rotary developing member, a cooling fan 52, and a solenoid 53. The components of the engine mechanism 50 are supplied with the power from the 24V power source. A fixing heater 54 is supplied with the power from the 100V power source through the triac (SSR) 110. The 5V power source is also connected to various sensors such as a density sensor and a display (not shown in FIG. 4).

When the main controller 11 receives no print instruction signal from the external computer for a fixed time, it determines with a timer etc. that printing operation has not been performed for a certain time. At that time, the main controller 11 issues “a stop instruction (standby-mode set instruction)” command to the engine controller 10 by its own determination. The main controller 11 sets a standby mode, or a nonprinting operation mode, for itself and also sets the nonprinting operation mode for the engine controller, thus setting both of them into the nonprinting operation mode.

when the print instruction signal from the external computer is inputted to the main controller 11, the nonprinting operation mode returns to a normal mode (printing operation mode). Briefly, the main controller 11 has a function for switching the operation mode of the image forming apparatus between the printing operation mode and the nonprinting operation mode. The engine controller 10 controls the components of the engine according to the operation-mode instruction signal from the main controller 11.

The CPU 101 of the engine controller 10 serves as a controller for disabling the writing of the lifetime management information to the FRAM 107 while the image forming apparatus operates in the nonprinting operation mode.

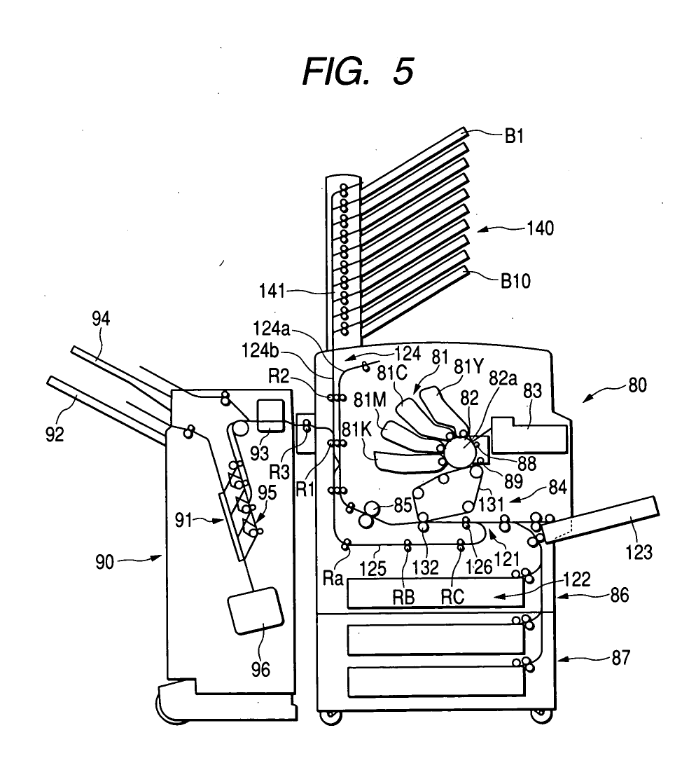

FIG. 5 is a schematic diagram of the structure of the image forming apparatus of the invention in which additional units are added to expand the function. In FIG. 5, an image forming apparatus 80 additionally includes a finisher 80 adjacent thereto, a multibin unit 140 above the image forming apparatus 80, and an optional paper-feed cassette 87 below the image forming apparatus 80.

The image forming apparatus 80 prints a full-color image onto a sheet of paper by overlaying four-color toners of yellow (Y), cyan (C), magenta (M), and black (K). The image forming apparatus 80 also prints a monochrome image onto a sheet of paper by using only a black (K) toner. As shown in FIG. 5, the casing accommodates a developing member 81, a photoreceptor unit 82, an exposure unit 83, a transfer unit 84, a fixing unit 85, and a paper feed/output unit 86.

The photoreceptor unit 82 includes a photoreceptor 82a (image supporting member) capable of counterclockwise rotation in the drawing. Around the photoreceptor 82a, a charging roller 88 serving as charging member, developing members 81Y, 81C, 81M, and 81K serving as developing member, and a cleaning section 89 are disposed along its rotating direction. Laser light is emitted from the exposure unit 83 toward the outer circumference of the photoreceptor 82a charged by the charging roller 88 to form an electrostatic latent image corresponding to the image forming instruction sent from the exterior of the apparatus, as will be described later. The developing members 81Y, 81C, 81M, and 81K serve as developing members that bear multiple color toners on the surfaces. When the image supporting member 82a rotates in a specified rotating direction, the different color toners of the developing members 81Y, 81C, 81M, and 81K sequentially face the photoreceptor 82a (image supporting member) to apply developing bias between the image supporting member 82a and the developing members 81Y, 81C, 81M, and 81K, thus moving the toners from the developing members 81Y, 81C, 81M, and 81K to the image supporting member 82a to develop the electrostatic latent image, thereby forming a toner image. The photoreceptor 82a thus serves as an image supporting member capable of supporting an electrostatic latent image.

The electrostatic latent image which is formed in this way is developed with toner by the developing member 81. Specifically, in this embodiment, the developing member 81 includes the yellow developing member 81Y, the cyan developing member 81C, the magenta developing member 81M, and the black developing member 81K along the photoreceptor 82a in this order. The developing members 81Y, 81C, 81M, and 81K can be brought close to and away from the photoreceptor 82a. One of the developing members 81Y, 81C, 81M, and 81K is selectively brought into contact with the photoreceptor 82a according to the instruction from the engine controller 10 to develop the electrostatic latent image on the photoreceptor 82a. In this way, the photoreceptor unit 82 forms a toner image corresponding to the image forming instruction on the photoreceptor 82a.

The toner image developed by the developing member 81 is first transferred on an intermediate transfer belt 131 of the transfer unit 84 in a primary transfer region between the black developing member 81K and the cleaning section 89. The transfer unit 84 includes a plurality of rollers, the intermediate transfer belt 131 laid across the rollers, and a secondary transfer roller 132 for secondarily transferring the intermediate toner image transferred to the intermediate transfer belt 131.

To transfer a color image onto a sheet of paper, different-color toner images formed on the photoreceptor 82a are overlaid on the intermediate transfer belt 131 to form the color image. In parallel, paper is ejected from a cassette 122, a manual paper tray 123, or an optional paper cassette 87 with a paper feeder 121 of the paper feed/output unit 86 and carried to a secondary transfer region. The color image is then secondarily transferred to the paper to form a full-color image.

To transfer a monochrome image onto a sheet of paper, only a black-toner image on the photoreceptor 82a is formed on the intermediate transfer belt 131 and transferred to a sheet of paper carried to the secondary transfer region, as with the color image, to form a monochrome image. In this embodiment, the intermediate transfer belt 131 serves as the image supporting member to construct image-forming device for forming an image on a sheet of paper with the photoreceptor unit 82, the exposure unit 83, and the transfer unit 84.

The sheet of paper to which the toner image has been transferred by the transfer unit 84 is carried by the paper feeder 121 of the paper feed/output unit 86 along a specified paper-feed path to the fixing unit 85 disposed downstream from the secondary transfer region, at which the image on the transferred paper is fixed. The paper is further carried to a paper output section 124 through a paper feed path.

The paper output section 124 includes two output paths 124a and 124b. The first output path 124a is led from the fixing unit 85 to a standard output tray. The second output path 124b extends almost in parallel with the first output path 124a and between a refeeding section 125 and the multibin unit 140. Three sets of roller pairs R1 to R3 are disposed along the output paths 124a and 124b. The roller pairs R1 to R3 are used to expel the fixed paper toward the standard output tray, a finisher 90, or the multibin unit 140. The roller pairs R1 to R3 are also used to carry the paper to the refeeding section 125 to form an image on the other side of the paper, or to form images on opposite sides of the paper.

As shown in FIG. 5, the refeeding section 125 carries the paper which is reversely carried from the paper output section 124 to a gate roller pair 126 of the paper feeder 121 through a refeeding path, which is constructed of three refeeding roller pairs Ra, Rb, and Rc disposed along the refeeding path. The paper carried from the paper output section 124 is thus returned to the gate roller pair 126 along the refeeding path, so that a no-image formed surface of the paper faces the intermediate transfer belt 131 in the paper feeder 121 to allow an image to be secondarily transferred to the surface.

The structure of the finisher 90 will then be briefly described with reference to FIG. 5. The finisher 90 has an ejected-paper inlet (not shown) on the side for receiving the paper ejected from the image forming apparatus 80. The ejected-paper inlet has a punch section 93 in the vicinity thereof for punching holes in the paper, which punches holes in the paper as necessary.

The paper carried into the finisher 90 is carried to a nonsorting tray 94 or to an intermediate tray 91 with a carrying mechanism 95. The intermediate tray 91 temporarily stores the paper carried from the image forming apparatus 80. When specified sheets of paper are stored in the intermediate tray 91, the stack of paper is stapled by a stapler 96 as necessary and then ejected onto a main tray 92.

The structure of the multibin unit 140 will now be described. The multibin unit 140 includes a common carrying path 141 for carrying image-formed paper carried into the unit by the paper output section (a carrying member) 124 of the image forming apparatus 80. Ten bins B1 to B10 branch from the common carrying path 141 at different positions and are stacked vertically. In this embodiment, the bin B10 is arranged upstream of the common carrying path 141, while the bins B9 to B1 are arranged downstream (upward in the drawing) in this order.

Branch tabs (not shown) corresponding to the branch positions one to one for switching the target of paper output are provided such that they can oscillate. The branch tabs are each oscillated by an output-destination switching controller of a multibin-unit controller, thereby selectively ejecting the paper carried through the common carrying path 141 to one of the bins B1 to B10.

The multibin unit has also been used as a mail box recently. When the multibin unit is used as the mail box, each bin is allocated as personal output bin. When an image forming instruction received by the image forming apparatus includes personal destination identifying information, more specifically, when image data including the bin number of the output destination is sent to a header section from an external device such as a host computer, the image forming apparatus outputs the image-formed paper to a bin of a designated bin number. This prevents paper to an individual from being mixed with paper to other persons, allowing the paper to a user oneself to be found easily. The use of the multibin unit as a mail box is useful particularly when one image forming apparatus is shared by multiple persons on a network.

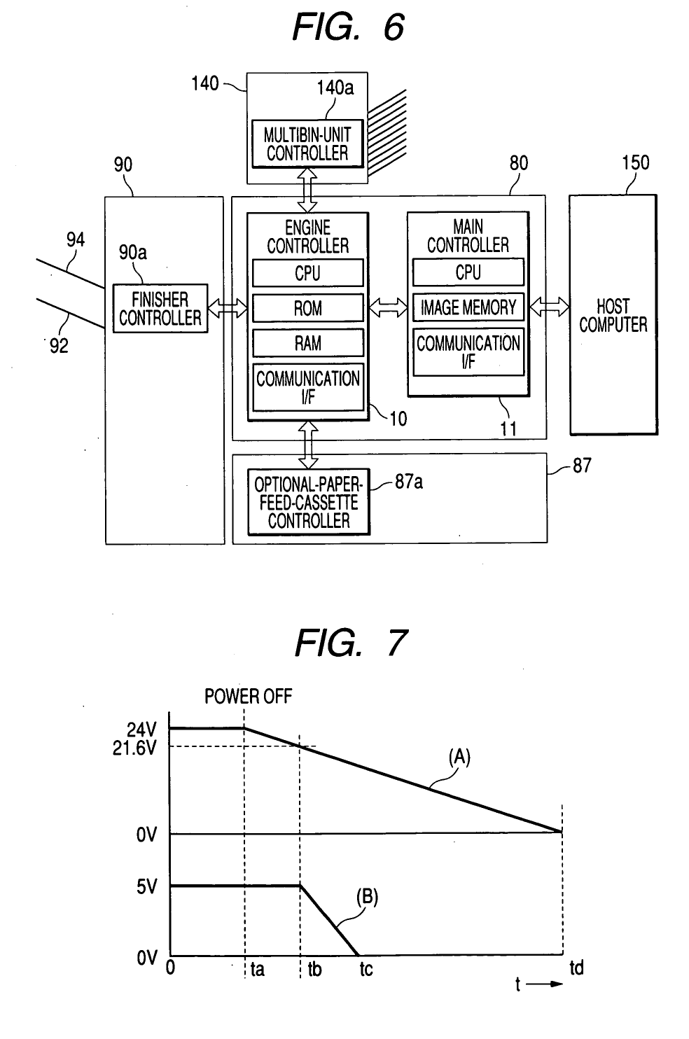

FIG. 6 is a block diagram of the electrical structure of the image forming apparatus of FIG. 5 including additional units. As shown in FIG. 6, the image forming apparatus 80 includes the main controller 11 and the engine controller 10 therein. The image forming apparatus 80 also includes the power source 70, shown in FIG. 5, and supplies the power of the 5V power source, the 24V power source, and the 100V power source to the finisher 90, the multibin unit 140, and the optional paper-feed cassette 87 as necessary.

The main controller 11 includes a CPU, an image memory, a communication interface, etc. Upon reception of an image forming instruction (a signal indicating print request details) from a host computer 150, the main controller 11 converts it to job data (print information) in the form suited for instruction of the operation of the components of the image forming apparatus 80 and transmits it to the engine controller 10.

The engine controller 10, which received the job data, includes a CPU, an ROM, an RAM, and a communication interface and controls the components of the image forming apparatus 80 according to the job data. The RAM can be replaced with an FRAM.

Correspondingly, the engine controller 10 sends various control signals to a finisher controller 90a via serial communication, the multibin-unit controller 140a, and an optional paper-feed cassette controller 87a to control, the finisher 90, the multibin unit 140, and the optional paper-feed cassette 87, respectively, thereby executing a printing process corresponding to the image forming instruction and other necessary processes. The controllers of the additional units are connected to the 5V power source. The finisher 90, the multibin unit 140, and the optional paper-feed cassette 87 include a driving system for carrying paper, to which the 24V power supply is connected.

The image forming apparatus according to the invention has a structure in which additional units such as a finisher, a multibin unit, and an optional paper-feed cassette can be added. The additional units are supplied with power from the power source 70 of the image forming apparatus, shown in FIG. 4. This increases the load connected to the 5V power source. The additional units, described in FIG. 5, can be mounted as appropriate to an image forming apparatus including the developer rotary unit shown in FIG. 2. Therefore, also in the image forming apparatus including the developer rotary unit, adding the additional units increases the load connected to the 5V power source.

The invention uses an FRAM having no limitation in number of times of writing as a memory for writing lifetime management information. The lifetime management information can thus be updated in the event of an unexpected accident such as main-power shutdown. Since the current consumption of the 24V power supply is reduced when the image forming apparatus is in nonprinting operation mode, the lifetime management information etc. are protected from being stored in memory.

The information is stored in the FRAM while the image forming apparatus is operated in printing operation mode, or during the period when a scanner motor is driven to increase the current consumption of the 24V power supply. Therefore, even when a high-capacity capacitor is not connected to the 5V power source, the lifetime management information can be stored in the FRAM during main-power shutdown. This decreases the cost of updating the image forming apparatus.

FIG. 1 is a characteristic diagram of an example of the voltage drop characteristics of the 24V power source and the 5V power source when main power is shut off. FIG. 1 shows the characteristics of the image forming apparatus during operation in the printing operation mode. FIG. 1 shows the case in which the main power is shut off at time ta. The 24V power source decreases in voltage with time to reach 0V at time tc, as in characteristic (C).

The 5V power source starts to decrease in voltage from time tb, later than time ta, to reach 0V at time tc, as in characteristic (B). The period from time ta when main power is shut off to time tb when the voltage of the 5V power source starts to decrease are almost equal in the nonprinting operation mode of FIG. 7 and in the printing operation mode of FIG. 1 because the CPU is in operation.

Since the 24V power source consumes much current in the printing operation mode, the voltage-drop rate during main-power shutdown is higher than that of the characteristic of FIG. 7. The time when the voltage of the 24V power source decreases 10% from the rated voltage is time tx, slightly later than ta at main-power shutdown. The 5V power source therefore has period (tb−tx) until time tb at which voltage drop starts. The period is approximately a few milliseconds to 10 milliseconds.

In FIG. 1, since a specified time is provided during the period after the main-power shutdown is detected from the specified level of decrease in voltage of the 24V power source until the voltage of the 5V power source starts to decrease. The CPU 101 of the engine controller 10 controls to write the lifetime management information etc. to the FRAM 107 within the period. According to the invention, necessary information such as lifetime management information can thus be stored in a memory even when main power is shut off. Since the process of writing the lifetime management information etc. to the FRAM requires no special control during main-power shutdown, the structure of the control system can be made simpler than that of the related ones.

Also, in the image forming apparatus, the writing of the lifetime management information to the memory is disabled during operation in the nonprinting operation mode, described in FIG. 7. However, in the printing operation mode, shown in FIG. 1, a specified time is provided after the main-power shutdown is detected by the decrease in voltage of the 24V power source to a specified level until the voltage of the 5V power source starts to decrease. The CPU 101 of the engine controller 10 controls the operation to write the lifetime management information etc. to the FRAM 107 within the period. Accordingly, in the embodiment of FIG. 1, necessary information such as lifetime management information can be stored in a memory even during main-power shutdown.

According to the invention, in the image forming apparatus including the rotary developing member and the intermediate transfer member, shown in FIG. 2, and the image forming apparatus including the developing member and the intermediate transfer member, shown in FIG. 5, the lifetime management information of the units used for image formation can be accurately updated, allowing unit replacement time to be grasped. Even when the load of the 5V power source is increased in order to connect additional units to expand the function of the image forming apparatus, the lifetime management information can be updated without problems. Since the lifetime management information is stored in the FRAM, there is no need for special control for limiting the number of times of writing, as in the case of using an EEPROM as memory, simplifying the structure of the control system.

The above-described embodiment is directed to an image forming apparatus capable of forming a full-color image using four color toners, yellow, cyan, magenta, and black. The toner colors and the number of colors of the invention is not limited to that but is free. For example, the invention can be applied to an apparatus that forms a monochrome image using only a black toner.

In the foregoing description, the supply voltage of the driving system is 24V and that of the control system is 5V. However, the supply voltage of the driving system connected to the driving-system components such as a motor can be set to a voltage other than 24V. The supply voltage of the control system connected to the control-system components such as a CPU can be set to a voltage other than 5V.

Although the present invention has been shown and described with reference to specific preferred embodiments, various changes and modifications will be apparent to those skilled in the art from the teachings herein. Such changes and modifications as are obvious are deemed to come within the spirit, scope and contemplation of the invention as defined in the appended claims.

1. An image forming apparatus, comprising:
a main power source, which includes:
a first power source, which supplies power to a high load unit;
a second power source, which supplies power to a low load unit;
a replaceable unit, which is used for image formation;
a switch, which switches between an image forming operation mode and a non-image forming operation mode; and
a memory, which is supplied with the power from the second power source,
wherein lifetime management information of the replaceable unit is stored in the memory during the image forming operation mode.

2. The image forming apparatus as set forth in claim 1, wherein the memory has a ferroelectric memory (FRAM).

3. The image forming apparatus as set forth in claim 1, wherein the power supplied from the first power source is greater than the power supplied from the second power source; and
wherein a current capacity of the high load unit is greater than that of the low load unit.

4. The image forming apparatus as set forth in claim 1, wherein a total current capacity of the high load unit in the image forming operation mode is greater than that of the high load unit in the non-image forming operation mode.

5. The image forming apparatus as set forth in claim 1, wherein an inclination of a voltage drop of the first power source after the main power source is shut off in the image forming operation mode is greater than that of the first power source after the main power source is shut off in the non-image forming operation mode.

6. The image forming apparatus as set forth in claim 1, wherein the image forming operation mode is same as the non-image forming operation mode in a period of the second power source from a shut off of the main power source until a voltage of the second power source starts to decrease.

7. The image forming apparatus as set forth in claim 1, wherein an additional unit which expands a function of the image formation is detachably mounted on the image forming apparatus; and
wherein the additional unit is supplied with the power from the second power source.

8. The image forming apparatus as set forth in claim 1, further comprising:
a detector, which detects a voltage drop of the first power source when the main power source is shut off,
wherein the lifetime management information is stored in the ferroelectric memory within a period from a voltage of the first power source decreases to a determined level until a voltage of the second power source starts to decrease.

9. The image forming apparatus as set forth in claim 1, further comprising:
an image supporting member, which supports an electrostatic latent image; and
a rotary developing member, which supports toners stored in a plurality of toner cartridges on a surface thereof,
wherein the rotary developing member carries different-color toners to a position opposed to the image supporting member in sequence by rotating in a specified rotating direction;
wherein a developing bias voltage is applied between the image supporting member and the rotary developing member;
wherein the toners are carried from the rotary developing member to the image supporting member; and
wherein the electrostatic latent image is developed so that a toner image is formed on the image supporting member.

10. The image forming apparatus as set forth in claim 1, further comprising:
an image supporting member, which supports an electrostatic latent image; and
a developing member, which is disposed around the image supporting member in a direction of rotation of the image supporting member, and which supports multiple-color toners on a surface thereof,
wherein the image supporting member carries the different-color toners of the developing member to a position opposed to the image supporting member in sequence by rotating in a specified rotating direction;
wherein a developing bias voltage is applied between the image supporting member and the developing member;
wherein the toners are carried from the developing member to the image supporting member; and
wherein the electrostatic latent image is developed so that a toner image is formed on the image supporting member.

11. The image forming apparatus as set forth in claim 9, wherein the toner image formed on the image supporting member is transferred to an intermediate transfer member.

12. A method of forming an image, comprising the steps of:
providing an image supporting member which supports an electrostatic latent image;
providing a replaceable unit used for image formation;
forming an image on the image supporting member in an image forming operation mode; and
storing lifetime management information of the replaceable unit in a ferroelectric memory (FRAM) which is connected to a control system power source in the image forming operation mode.

13. The method as set forth in claim 12, further comprising the steps of:
detecting voltage of a driving system power source;
first determining whether or not the voltage of the driving system power source is decreased to a specified level;
second determining whether or not a main power source is shut off based on the first determining step; and
storing lifetime management information of the replaceable unit in the ferroelectric memory within a period from a shutoff of the main power source is detected until a voltage of a control system power source supplied with power from the main power source starts to decrease.

14. An image forming apparatus, comprising:
a main power source, which includes:
a first power source, which supplies power to a high load unit;
a second power source, which supplies power to a low load unit;
a replaceable unit, which is used for image formation;
a switch, which switches between an image forming operation mode and a non-image forming operation mode;
a memory, which is supplied with the power from the second power source; and
a controller, which restricts a storing of lifetime management information of the replaceable unit in the memory during the non-image forming operation mode.

15. The image forming apparatus as set forth in claim 14, wherein the memory has a ferroelectric memory (FRAM).

16. A method of forming an image, comprising the steps of:
providing an image supporting member which supports an electrostatic latent image;
providing a replaceable unit used for image formation;
forming an image on the image supporting member in an image forming operation mode; and
restricting a storing of lifetime management information of the replaceable unit in a ferroelectric memory (FRAM) which is connected to a control system power source in a non-image forming operation mode.
